(19) United States
(12) Patent Application Publication
(10) Pub. No.: US 2024/0165766 A1
(43) Pub. Date: May 23, 2024

(54) GRINDING METHOD OF WORKPIECE

(71) Applicant: DISCO CORPORATION, Tokyo (JP)

(72) Inventors: Mato HATTORI, Tokyo (JP); Hironobu OZAWA, Tokyo (JP)

(21) Appl. No.: 18/509,631

(22) Filed: Nov. 15, 2023

(30) Foreign Application Priority Data
Nov. 21, 2022 (JP) 2022-185543

(51) Int. Cl. B24B 37/013

(52) U.S. Cl. CPC B24B 37/013

(57) ABSTRACT

A grinding method of a workpiece includes a holding step of holding the workpiece on a holding surface of a chuck table, a grinding step of, after the holding step, measuring a thickness of the workpiece in a non-contact region other than a contact region between the workpiece and grinding stones while grinding the workpiece with a grinding wheel including the grinding stones, and a measurement step of, after the grinding step, relatively moving and separating the workpiece and the grinding stones from each other, and measuring the thickness of the workpiece in the contact region during or after the relative movement of the workpiece and the grinding stones.

### BACKGROUND OF THE INVENTION

### Field of the Invention

The present invention relates to a grinding method of a workpiece that grinds the workpiece with a grinding wheel.

### Description of the Related Art

Device chips with devices included therein are manufactured by dividing a wafer, on which the devices are formed, into individual chips. Further, a package substrate is formed by mounting such device chips on a predetermined substrate, and covering and sealing the mounted device chips with a resin layer (mold resin). By dividing and singulating such a package substrate, package devices are each manufactured including a plurality of ones of the packaged devices. Device chips and package devices are incorporated in various pieces of electronic equipment such as mobile phones and personal computers.

Reflecting a move toward smaller electronic equipment in recent years, there is a growing demand for thinner device chips and package devices. Processing may hence be performed to grind and thin a wafer or package substrate with a grinding apparatus before its division. The grinding apparatus includes a chuck table having a holding surface that holds a workpiece, and a grinding unit that applies grinding processing to the workpiece. A spindle is built in the grinding unit, and an annular grinding wheel with a plurality of grinding stones included therein is mounted on a distal end portion of the spindle. The workpiece is ground and thinned by holding the workpiece on the holding surface of the chuck table, and bringing the grinding stones into contact with the workpiece while rotating the chuck table and the grinding wheel (see JP 2009-141176A).

When grinding the workpiece by the grinding apparatus, a tilt of the chuck table with the grinding wheel is adjusted. Described specifically, the workpiece is actually ground by the grinding wheel, and after the grinding, the workpiece is measured for a thickness distribution. Based on the thickness distribution of the workpiece, the tilt angle of the chuck table or grinding wheel is set such that the workpiece is reduced in thickness variations. If the tilt of the chuck table or grinding wheel is adjusted as described above, however, there is a need to actually grind, before adjusting the tilt, at least one workpiece and to measure the thickness distribution of the workpiece. However, the workpiece used in the measurement of the thickness distribution may fail to meet predetermined specifications and may not be used in the manufacture of actual products, because the workpiece is ground without any advance tilt adjustment and is prone to have large thickness distributions.

A method has therefore been proposed to adjust the tilt of a chuck table in the course of grinding of a workpiece (see JP 2013-119123A). With this method, at a stage where the grinding has progressed to a certain extent, the grinding of the workpiece is temporarily suspended, and the thickness distribution of the workpiece is measured. After the tilt of the chuck table is then adjusted based on the thickness distribution, the grinding of the workpiece is resumed. This enables to grind the workpiece, which has been used for the measurement of the thickness distribution, with an advance tilt adjustment. As a result, the workpiece is reduced in final thickness variations, thereby decreasing the number of workpieces that cannot be used in the manufacture of actual products.

### SUMMARY OF THE INVENTION

During the grinding of the workpiece, the grinding stones of the grinding wheel remain in contact with the workpiece, so that the thickness of the workpiece cannot be measured in a contact region between the workpiece and the grinding stones. When measuring the thickness distribution of the workpiece, the grinding stones are therefore separated from the workpiece in the course of or after the grinding of the workpiece and the thickness of the workpiece is then measured in a region from a center to an outer peripheral edge of the workpiece. However, a certain length of time is needed to measure the thickness distribution of the workpiece. During the measurement of the thickness distribution, there is hence a need to stand by without applying other procedures (processing, a transfer, and the like) to the workpiece while holding the workpiece on the chuck table. This leads to a longer standby time, thereby causing a problem that the efficiency of grinding processing of the workpiece is lowered. If desired to measure the thickness distribution of the workpiece in the course of the grinding of the workpiece as mentioned above, for example, the grinding of the workpiece cannot be resumed until completion of the measurement of the thickness distribution, thereby reducing the efficiency of the grinding processing.

With such problems in view, the present invention has as an object thereof the provision of a grinding method of a workpiece, which can make improvements in the efficiency of grinding processing of a workpiece.

In accordance with an aspect of the present invention, there is provided a grinding method of a workpiece including a holding step of holding the workpiece on a holding surface of a chuck table, a grinding step of, after the holding step, measuring a thickness of the workpiece in a non-contact region other than a contact region between the workpiece and grinding stones while grinding the workpiece with a grinding wheel including the grinding stones, and a measurement step of, after the grinding step, relatively moving and separating the workpiece and the grinding stones from each other, and measuring the thickness of the workpiece in the contact region during or after the relative movement of the workpiece and the grinding stones.

Preferably, in the grinding step and the measurement step, the thickness of the workpiece may be measured at three or more points of different distances from a center of the workpiece, and the grinding method may further include a tilt adjustment step of, after the measurement step, adjusting a relative tilt between the holding surface and the grinding wheel based on the thicknesses of the workpiece measured in the grinding step and the measurement step. Also preferably, the grinding step, the measurement step, and the tilt adjustment step may each be performed a plurality of times to grind the workpiece.

With the grinding method according to the aspect of the present invention, the thickness of the workpiece is measured in the non-contact region during grinding of the workpiece, and after the grinding of the workpiece, the thickness of the workpiece is measured in the contact region. This shortens the measuring time of the thickness of the workpiece after the grinding of the workpiece, and therefore makes improvements in the efficiency of grinding processing of the workpiece.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view illustrating a grinding apparatus;

FIG. 2 is a partially cross-sectional front view illustrating a chuck table;

FIG. 3 is a flow chart illustrating a grinding method according to an embodiment of the present invention for a workpiece;

FIG. 4A is a perspective view illustrating the grinding apparatus in a holding step;

FIG. 4B is a partially cross-sectional front view illustrating the grinding apparatus in the holding step;

FIG. 5A is a perspective view illustrating the grinding apparatus in a grinding step;

FIG. 5B is a partially cross-sectional front view illustrating the grinding apparatus in the grinding step;

FIG. 6A is a perspective view illustrating the grinding apparatus in a measurement step; and

FIG. 6B is a partially cross-sectional front view illustrating the grinding apparatus in the measurement step.

### DETAILED DESCRIPTION OF THE PREFERRED EMBODIMENT

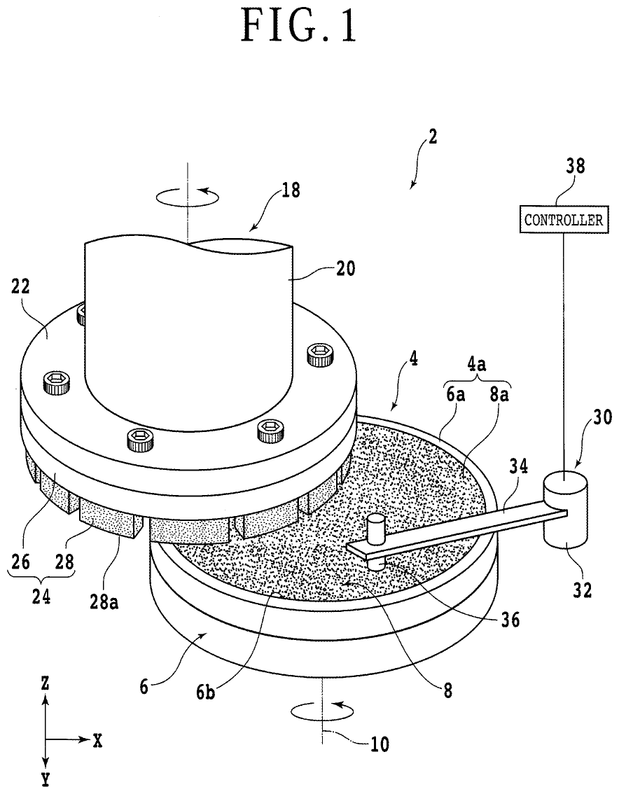

With reference to the attached drawings, a description will hereinafter be made about an embodiment of the present invention. A description will first be made about a configuration example of a grinding apparatus that can be used in practicing the grinding method according to this embodiment. FIG. 1 is a perspective view illustrating a grinding apparatus 2. It is to be noted that in FIG. 1, an X-axis direction (first horizontal direction) and a Y-axis direction (second horizontal direction) are directions perpendicular to each other. It is also to be noted that a Z-axis direction (processing feed direction, height direction, vertical direction, or up-down direction) is a direction perpendicular to the X-axis direction and Y-axis direction.

The grinding apparatus 2 includes a chuck table (holding table) 4 that holds a workpiece to be subjected to grinding processing by the grinding apparatus 2. The chuck table 4 includes a cylindrical frame body (main body portion) 6 made from metal such as stainless steel (SUS), glass, ceramics, resin, or the like. A cylindrical recessed portion 6b is disposed in a central portion on a side of an upper surface 6a of the frame body 6. A disk-shaped holding member 8 made from a porous material such as porous ceramics is fitted in the recessed portion 6b of the frame body 6. The holding member 8 includes a number of pores communicating from an upper surface to a lower surface of the holding member 8. The upper surface of the holding member 8 configures a circular suction surface 8a that draws the workpiece under suction when holding the workpiece on the chuck table 4.

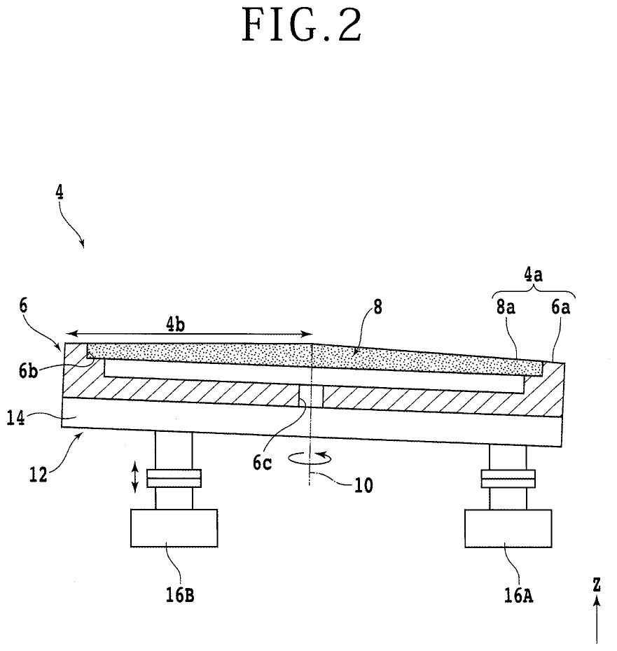

FIG. 2 is a partially cross-sectional front view illustrating the chuck table 4. By the upper surface 6a of the frame body 6 and the suction surface 8a of the holding member 8, a holding surface 4a of the chuck table 4 is configured. The holding surface 4a is connected to a suction source (not illustrated) such as an ejector via the pores included in the holding member 8, a flow passage 6c disposed inside the frame body 6, a valve (not illustrated), and the like.

The holding surface 4a of the chuck table 4 is formed in a circular conical shape having an apex at a center of the holding surface 4a, and is slightly inclined to a radial direction of the holding surface 4a. The chuck table 4 is arranged in a slightly tilted position such that a holding region 4b, which corresponds to a part of the holding surface 4a and extends from the center to an outer peripheral edge of the holding surface 4a, lies substantially parallel to a horizontal plane (X-Y plane). By a below-mentioned grinding unit 18, the workpiece is ground in a region where the workpiece is held on the holding region 4b and its vicinities of the holding surface 4a. It is to be noted that in FIG. 2, the tilt of the holding surface 4a is illustrated exaggerated for the sake of convenience of the description although the actual tilt of the holding surface 4a is small. If the holding surface 4a has a diameter of approximately 290 mm or greater and 310 mm or smaller, for example, the difference in height between the center and the outer peripheral edge of the holding surface 4a, the difference corresponding to the height of a circular cone, is set to approximately 20 μm or greater and 40 μm or smaller.

To the chuck table 4, a rotary drive source (not illustrated) such as a motor is connected to rotate the chuck table 4 about an axis of rotation 10. The axis of rotation 10 of the chuck table 4 is set along a direction perpendicular to the radial direction of the holding surface 4a, and is slightly inclined to the Z-axis direction. Further, the axis of rotation 10 crosses the holding surface 4a such that it passes through the center of the holding surface 4a.

To the chuck table 4, a tilt adjustment mechanism 12 is also connected to adjust the tilt of the chuck table 4. The tilt adjustment mechanism 12 includes, for example, a disk-shaped table base 14 that supports the chuck table 4 via bearings (not illustrated), and a single fixed support member 16A and two movable support members 16B, which support the table base 14. It is to be noted that in FIG. 2, only one of the movable support members 16B is illustrated, and illustration of the other movable support member 16B is omitted.

The single fixed support member 16A and two movable support members 16B are arranged at substantially equal intervals (120° intervals) along the direction of a periphery of the table base 14. An upper end of the fixed support member 16A and upper ends of the movable support members 16B are each fixed to a side of a lower surface of an outer peripheral portion of the table base 14. The fixed support member 16A is configured such that its upper end is fixed at a predetermined height. On the other hand, the movable support members 16B are configured such that their upper ends are movable (liftable up and down) along the Z-axis direction. By inputting control signals from a below-mentioned controller 38 (see FIG. 1) to the movable support members 16B, the positions in the Z-axis direction (height positions) of the upper ends of the two movable support members 16B can be changed respectively. This enables to change the tilt of the chuck table 4 and axis of rotation 10, so that the angle of the holding region 4b with respect to the horizontal direction can be adjusted.

To the chuck table 4, a moving unit (not illustrated) is also connected to move the chuck table 4 along the horizontal direction (X-Y plane direction). The moving unit is configured, for example, by a moving mechanism of the ball screw type or a turntable.

As illustrated in FIG. 1, the grinding unit 18 is disposed above the chuck table 4 to apply grinding processing to the workpiece. The grinding unit 18 includes a cylindrical spindle 20 arranged along the Z-axis direction. To a proximal end portion (upper end portion) of the spindle 20, a rotary drive source (not illustrated) such as a motor is connected to rotate the spindle 20. When the rotary drive source is driven, the spindle 20 is rotated about an axis of rotation that is set along the Z-axis direction.

On a distal end portion (lower end portion) of the spindle 20, a disk-shaped wheel mount 22 made from metal or the like is fixed. On a side of a lower surface of the wheel mount 22, an annular grinding wheel 24 is detachably secured to grind the workpiece. The grinding wheel 24 is fixed on the wheel mount 22 by fixtures such as bolts.

The grinding wheel 24 includes an annular wheel base 26, which is made from metal such as aluminum or stainless steel and is formed with substantially the same diameter as the wheel mount 22. The wheel base 26 is fixed on a side of an upper surface thereof to a side of a lower surface of the wheel mount 22. On a side of a lower surface of the wheel base 26, a plurality of grinding stones 28 is fixed. For example, the grinding stones 28 are formed in a parallelepiped shape, and are arrayed at substantially equal intervals in an annular pattern along the direction of a periphery of the wheel base 26. Lower surfaces of the grinding stones 28 configure grinding surfaces 28a that grind the workpiece. The grinding stones 28 contain abrasive grains made of diamond, cubic boron nitride (cBN), or the like, and a binder (bonding material), such as a metal bond, resin bond, or vitrified bond, that fixes the abrasive grains. No limitations are however imposed on the material, shape, construction, size, and the like of the grinding stones 28. Further, the number of the grinding stones 28 can be set as desired.

By power transmitted from the rotary drive source (not illustrated) via the spindle 20 and wheel mount 22, the grinding wheel 24 is rotated about an axis of rotation that is substantially parallel to the Z-axis direction. When the grinding wheel 24 is rotated, the grinding stones 28 are caused to rotate about the axis of rotation of the spindle 20 and along a rotation track (rotation path) substantially parallel to the horizontal plane (X-Y plane).

To the grinding unit 18, a moving unit (not illustrated) is connected to move (lift up and down) the grinding unit 18 along the Z-axis direction. The moving unit is configured, for example, by a Z-axis moving mechanism of the ball screw type that moves the grinding unit 18 along the Z-axis direction. If this is the case, the Z-axis moving mechanism includes a ball screw (not illustrated) arranged along the Z-axis direction, a pulse motor (not illustrated) that rotates the ball screw, and a nut portion (not illustrated) that is connected to the grinding unit 18 and maintained in threaded engagement with which the ball screw. When the grinding unit 18 is lifted up or down by the Z-axis moving mechanism, the chuck table 4 and the grinding wheel 24 are caused to relatively move along the Z-axis direction, and hence to separate or approach each other.

Inside or adjacent to the grinding unit 18, a grinding fluid supply channel (not illustrated) is disposed to supply a liquid (grinding fluid) such as pure water. When grinding the workpiece by the grinding wheel 24, the grinding fluid is supplied to the workpiece and the grinding stones 28. As a consequence, the workpiece and the grinding stones 28 are cooled, and at the same time debris (grinding debris) occurred by grinding processing is washed away.

At a side of the chuck table 4, a measurement unit 30 is disposed to measure the thickness of the workpiece held on the chuck table 4. The measurement unit 30 includes, for example, a cylindrical rotational support portion 32, and a strip-shaped support arm 34 connected to the rotational support portion 32. To a proximal end portion (lower end portion) of the rotational support portion 32, a rotary drive source (not illustrated) such as a motor is connected to rotate the rotational support portion 32 about an axis of rotation that is substantially parallel to the Z-axis direction. Further, the proximal end portion of the support arm 34 is fixed on the rotational support portion 32, and the support arm 34 is arranged substantially parallel to the horizontal plane (X-Y plane).

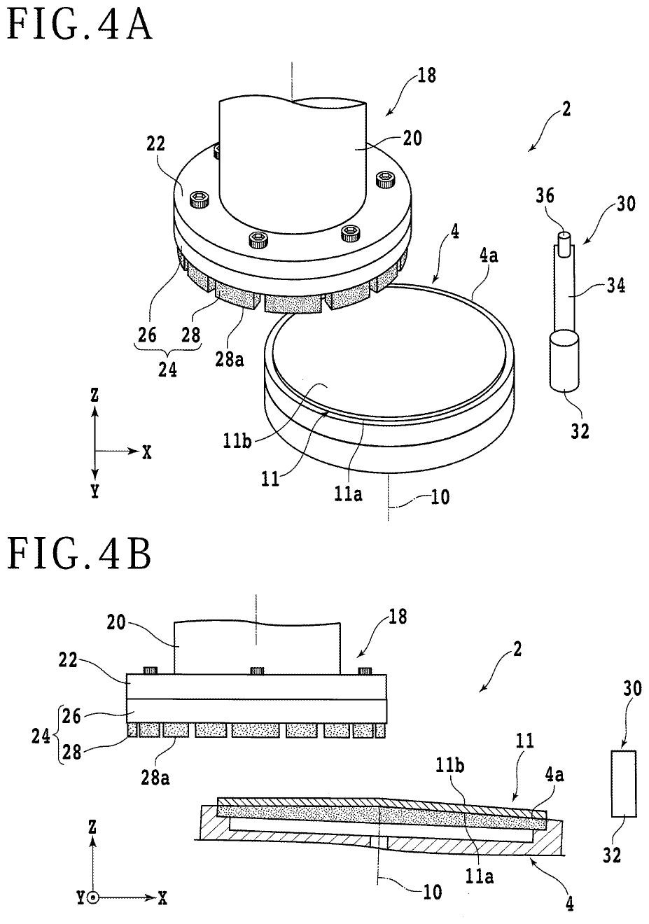

On a distal end portion of the support arm 34, a measuring device (thickness gauge) 36 is secured to measure the thickness of the workpiece. No limitation is imposed on the kind of the measuring device 36, and an optical interference thickness gauge, an ultrasonic thickness gauge, or the like can be used, for example. It is to be noted that a contactless thickness gauge, which does not come into direct contact with the workpiece, is preferred because the measuring device 36 measures the thickness of the rotating workpiece as will be mentioned subsequently herein. In addition, the height position of the holding surface 4a may be measured and stored beforehand, and the height position of an upper surface of a workpiece 11 (see FIG. 4A) may be measured by the measuring device 36. If this is the case, the thickness of the workpiece 11 can be calculated based on a difference between the height position of the holding surface 4a and the height position of the upper surface of the workpiece 11.

When the rotational support portion 32 is rotated by driving the rotary drive source (not illustrated), the support arm 34 and measuring device 36 are caused to turn about the axis of rotation of the rotational support portion 32. As a consequence, the measuring device 36 can be positioned at a location (measurement location) where the measuring device 36 overlaps the holding surface 4a, or at a location (retreated location) where the measuring device 36 does not overlap the holding surface 4a. The length of the support arm 34 and the secured position of the measuring device 36 are adjusted, for example, such that the measuring device 36 is allowed to turn while passing through a location overlapping the center of the holding surface 4a in the Z-axis direction.

The grinding apparatus 2 includes the controller (control unit, control section, control device) 38 that controls the grinding apparatus 2. The controller 38 is connected to elements (chuck table 4, tilt adjustment mechanism 12, grinding unit 18, measurement unit 30, and the like) of the grinding apparatus 2, and generates control signals to control operations of the individual elements. For example, the controller 38 is configured by a computer, and includes a processing unit that performs processing needed to operate the grinding apparatus 2, and a storage unit that stores various information (data, programs, and the like) to be used in the operation of the grinding apparatus 2. The processing unit is configured including a processor such as a central processing unit (CPU). The storage unit is configured including a memory such as a read only memory (ROM) or a random access memory (RAM).

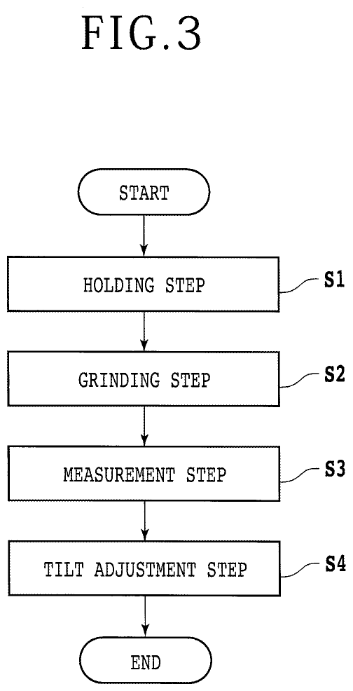

A description will next be made about a specific example of the grinding method according to this embodiment. FIG. 3 is a flow chart illustrating the grinding method of the workpiece. In this embodiment, the thickness of the workpiece is measured while grinding the workpiece with the grinding apparatus 2.

Described specifically, the workpiece is first held on the holding surface 4a of the chuck table 4 (holding step S1). FIG. 4A is a perspective view illustrating the grinding apparatus 2 in the holding step S1, and FIG. 4B is a partially cross-sectional front view illustrating the grinding apparatus 2 in the holding step S1.

In the holding step S1, the workpiece 11 to be ground by the grinding apparatus 2 is held on the chuck table 4. For example, the workpiece 11 is a disk-shaped wafer made from a semiconductor material such as single crystal silicon, and includes a front surface (first surface) 11a and a back surface (second surface) 11b, which are substantially parallel to each other. The workpiece 11 is defined into a plurality of rectangular regions by a plurality of streets (scribe lines) arrayed in a grid pattern such that they intersect together. Further, the regions defined by the streets are formed on the side of the front surface 11a with devices such as integrated circuits (ICs), large scale integrations (LSIs), light emitting diodes (LEDs), or micro electro mechanical systems (MEMS) devices, respectively. By dividing the workpiece 11 along the streets, a plurality of devices chips is manufactured with the devices included respectively therein. If the workpiece 11 is thinned before its division by grinding the workpiece 11 on a side of the back surface 11b with the grinding apparatus 2, thinned device chips are obtained. No limitations are however imposed on the material, shape, construction, size, and the like of the workpiece 11. For example, the workpiece 11 may be a substrate (wafer) made from a semiconductor (GaAs, InP, GaN, SiC, or the like) other than silicon, a glass (silica glass, borosilicate glass, or the like), a ceramic, a resin, a metal, or the like. Further, no limitations are imposed on the kind, number, shape, construction, size, arrangement or the like of the devices, and no devices may be formed on the workpiece 11.

In the holding step S1, the rotational support portion 32 of the measurement unit 30 is first rotated to position the support arm 34 and measuring device 36 at locations (retreated locations) where they do not overlap the holding surface 4a of the chuck table 4. This can avoid any interference between the workpiece 11 and the measurement unit 30 in the holding step S1.

Next, the workpiece 11 is arranged on the chuck table 4. The workpiece 11 is arranged on the holding surface 4a such that the side of the front surface 11a faces the holding surface 4a and the side of the back surface 11b (the surface to be ground) is exposed upward. At this time, the workpiece 11 is positioned concentrically with the holding surface 4a such that the axis of rotation 10 of the chuck table 4 passes through a center of the workpiece 11. In addition, the suction surface 8a (see FIG. 2) of the chuck table 4 is covered in its entirety by the workpiece 11. When a suction force (negative pressure) of the suction source is caused to act on the holding surface 4a with the workpiece 11 arranged on the chuck table 4, the workpiece 11 is held under suction on the chuck table 4. It is to be noted that the holding surface 4a is formed in the circular conical shape (see FIG. 2) as mentioned above. The workpiece 11 is therefore held in a form slightly deformed along the holding surface 4a when the workpiece 11 is drawn under suction through the chuck table 4.

When holding the workpiece 11 on the chuck table 4, a protective member (not illustrated) may be fixed on the side of the front surface 11a of the workpiece 11. The protective member is fixed so as to cover the workpiece 11 in its entirety on the side of the front surface 11a, and protects the workpiece 11 on the side of the front surface 11a. The workpiece 11 is then held on the holding surface 4a of the chuck table 4 via the protective member. As the protective member, a circular sheet (protective sheet) formed with substantially the same diameter as the workpiece 11 can be used. The protective sheet includes, for example, a film-shaped base material, and a self-adhesive layer (glue layer) disposed on the base material. The base material is made from a resin such as a polyolefin, polyvinyl chloride, or polyethylene terephthalate, whereas the self-adhesive layer is formed from an epoxy-based, acrylic, or rubber-based adhesive, or the like. As an alternative, the self-adhesive layer may also be formed from a UV-curable resin that is cured by irradiation of ultraviolet rays.

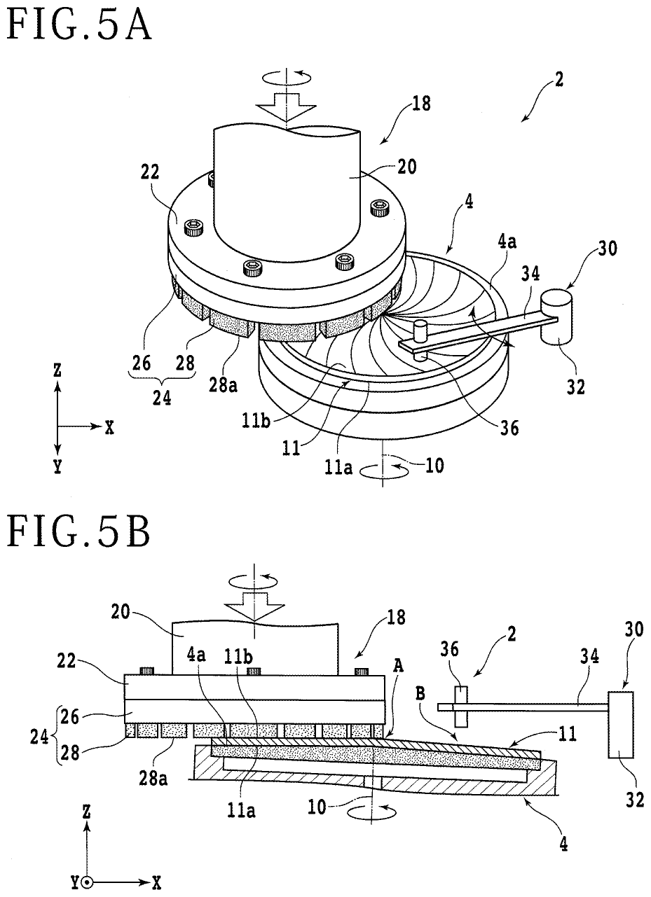

While grinding the workpiece 11 by the grinding wheel 24, the thickness of the workpiece 11 is next measured in a non-contact region other than a contact region between the workpiece 11 and the grinding stones 28 (grinding step S2). FIG. 5A is a perspective view illustrating the grinding apparatus 2 in the grinding step S2, and FIG. 5B is a partially cross-sectional front view illustrating the grinding apparatus 2 in the grinding step S2.

In the grinding step S2, a positional relation between the chuck table 4 and the grinding wheel 24 is first adjusted. Described specifically, the chuck table 4 is moved along the horizontal direction (X-Y plane direction) to position the chuck table 4 such that the center of the workpiece 11 and the rotation track of the grinding stones 28 overlap in the Z-axis direction. It is to be noted that the rotation track of the grinding stones 28 has a diameter greater than the radius of the workpiece 11, and that the grinding stones 28 are arranged to overlap an arc-shaped region extending from the center to an outer peripheral edge of the workpiece 11.

Next, the chuck table 4 is rotated about the axis of rotation 10, and at the same time, the spindle 20, wheel mount 22, and grinding wheel 24 are rotated about the axis of rotation substantially parallel to the Z-axis direction. With the chuck table 4 and grinding wheel 24 kept rotating, the grinding unit 18 is lifted down along the Z-axis direction. As a consequence, the chuck table 4 and the grinding wheel 24 are relatively moved along a direction (Z-axis direction) parallel to the axis of rotation of the spindle 20, so that the workpiece 11 and the grinding stones 28 are caused to approach and come into contact with each other. When the grinding surfaces 28a of the grinding stones 28 come into contact with the workpiece 11, the grinding stones 28 grind the entirety on the side of the back surface 11b of the workpiece 11 while rotating so as to pass through the axis of rotation 10 of the chuck table 4. As a consequence, the workpiece 11 is thinned in its entirety. The grinding of the workpiece 11 is continued until the thickness of the workpiece 11 is reduced to a finish thickness (a target value for the final thickness of the workpiece 11).

During the grinding of the workpiece 11, the rotational support portion 32 of the measurement unit 30 is also rotated to arrange the measuring device 36 such that the measuring device 36 overlaps a non-contact region B other than a contact region A where the workpiece 11 and the grinding stones 28 come into contact with each other. Described specifically, the measuring device 36 is positioned such that neither the support arm 34 nor the measuring device 36 comes into contact with the grinding wheel 24. This can avoid any interference between the grinding wheel 24 and the measurement unit 30. While the workpiece 11 is being ground by the grinding wheel 24, the measuring device 36 measures the thickness of the workpiece 11 in the non-contact region B. In the grinding step S2, the grinding of the workpiece 11 and the measurement of the thickness of the workpiece 11 are therefore performed concurrently in parallel.

In the grinding step S2, the thickness of the workpiece 11 is measured a plurality of times by the measuring device 36 while moving (turning) the measuring device 36 within a range in which the grinding wheel 24 and the measurement unit 30 remain out of contact with each other. As a consequence, the thickness of the workpiece 11 is measured at two or more points of different distances from the center of the workpiece 11, and the thickness distribution of the workpiece 11 in the region (non-contact region B) other than a central portion (contact region A) of the workpiece 11 is obtained. The measuring device 36 measures, for example, the thickness of the workpiece at the outer peripheral edge thereof, and the thickness of the workpiece 11 at an intermediate point between the center and the outer peripheral edge thereof. It is to be noted that the measurement of the thickness of the workpiece 11 may be performed a plurality of times at every measurement point. It is also to be noted that a detailed thickness distribution in the radial direction of the workpiece 11 may be obtained in the non-contact region B by successively measuring the thickness of the workpiece 11 while moving (turning) the measuring device 36.

Information on the thickness of the workpiece 11 in the non-contact region B as measured by the measuring device 36 is outputted to the controller 38. The controller 38 then stores in the storage unit (memory) the information on the thickness of the workpiece 11 as inputted from the measuring device 36.

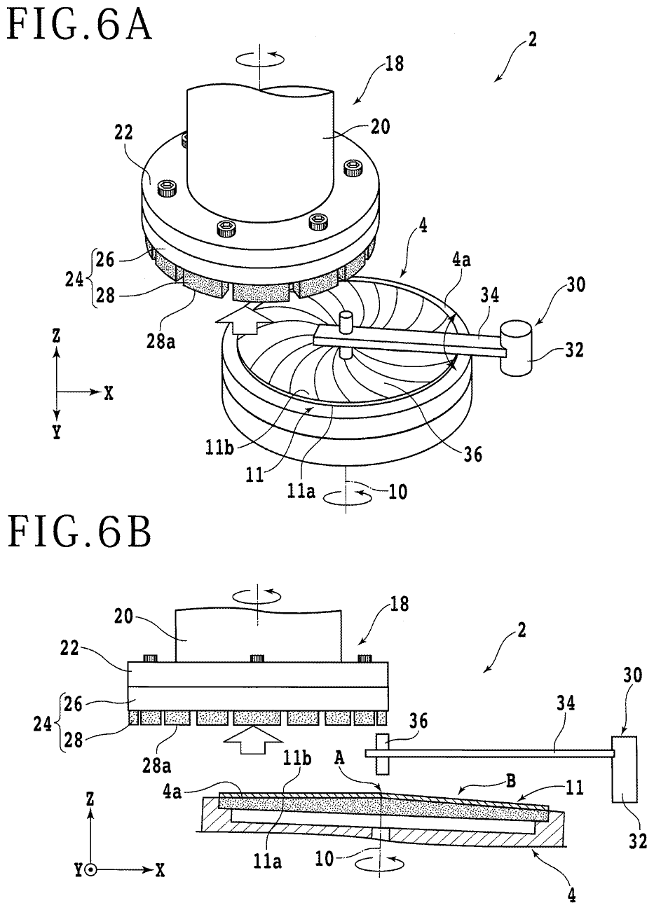

Next, the workpiece 11 and the grinding stones 28 are relatively moved and are separated from each other, followed by a measurement of the thickness of the workpiece 11 in the contact region A (measurement step S3). FIG. 6A is a perspective view illustrating the grinding apparatus 2 in the measurement step S3, and FIG. 6B is a partially cross-sectional front view illustrating the grinding apparatus 2 in the measurement step S3.

In the measuring step S3, the grinding unit 18 is first lifted up, whereby the workpiece 11 and the grinding stones 28 are relatively moved and are separated from each other. As a consequence, the grinding of the workpiece 11 by the grinding stones 28 is suspended. It is to be noted that the lift-up distance of the grinding unit 18 is set so as to enable passage of the measuring device 36 of the measurement unit 30 between the workpiece 11 and the grinding stones 28.

The rotational support portion 32 of the measurement unit 30 is next rotated to move the measuring device 36 to between the workpiece 11 and the grinding stones 28. The measuring device 36 is then positioned at a location overlapping the contact region A that corresponds to the region in which the workpiece 11 and the grinding stones 28 were in contact with each other in the grinding step S2, and the thickness of the workpiece 11 is measured by the measuring device 36 in the contact region A. In the measuring step S3, the measuring device 36 is therefore arranged at the location where its arrangement was infeasible due to an interference (contact) between the grinding unit 18 and the measurement unit 30 in the grinding step S2, and measures the thickness of the workpiece 11 at the location. If the workpiece 11 and the grinding stones 28 are relatively positioned such that the rotation track of the grinding stones 28 overlap the center of the workpiece 11, the grinding stones 28 remain in contact with the central portion of the workpiece 11 during the grinding of the workpiece 11, so that the thickness of the central portion of the workpiece 11 cannot be measured in the above-mentioned grinding step S2 (see FIGS. 5A and 5B). In the measurement step S3, the thickness of the central portion of the workpiece 11 is therefore measured by the measuring device 36 by positioning the measuring device 36 right above the center of the workpiece 11 after separating the grinding stones 28 from the workpiece 11.

The measurement of the thickness of the workpiece 11 in the measurement step S3 can be performed during or after the relative movement of the workpiece 11 and the grinding stones 28. Described specifically, the thickness of the workpiece 11 may be measured by positioning the measuring device 36 right above the contact region A while the grinding unit 18 is being lifted up, or the thickness of the workpiece 11 may also be measured by positioning the measuring device 36 right above the contact region A after the lift-up of the grinding unit 18 has stopped. Especially when the thickness of the workpiece 11 is measured during the relative movement of the workpiece 11 and the grinding stones 28, it is possible to promptly move to a next procedure after completion of the lift-up of the grinding unit 18.

In the measurement step S3, the thickness of the workpiece 11 is measured at at least one point. The measuring device 36 measures the thickness of the workpiece 11, for example, at the center thereof. It is to be noted that the measurement of the thickness of the workpiece 11 may be performed a plurality of times at every measurement point. It is also to be noted that a detailed thickness distribution in the radial direction of the workpiece 11 may be obtained in the contact region A by successively measuring the thickness of the workpiece 11 while moving (turning) the measuring device 36.

Information on the thickness of the workpiece 11 in the contact region A as measured by the measuring device 36 is outputted to the controller 38. The controller 38 then stores in the storage unit (memory) the information on the thickness of the workpiece 11 as inputted from the measuring device 36.

As described above, in this embodiment, the thickness of the workpiece 11 is measured in the non-contact region B in the grinding step S2 while grinding the workpiece 11, and the thickness of the workpiece 11 is measured in the contact region A in the measurement step S3 by separating the grinding stones 28 from the workpiece 11. The measurement of the thickness of the workpiece 11, which has conventionally been performed after the grinding processing, is hence performed, in part, during the grinding of the workpiece 11. As a consequence, the time required for the measurement of the thickness of the workpiece after the grinding processing is shortened, thereby making it possible to promptly move to subsequent procedures (transfer, processing, and the like). As a result, the efficiency of grinding processing of the workpiece 11 is improved.

After the performance of the grinding step S2 and measurement step S3, an evaluation of the workpiece 11 and adjustments of elements of the grinding apparatus 2 may be performed based on the thicknesses of the workpiece 11 as measured by the measurement unit 30. For example, the relative tilt of the holding surface 4a of the chuck table 4 and the grinding wheel 24 is adjusted based on the thicknesses of the workpiece 11 as measured in the grinding step S2 and measurement step S3 (tilt adjustment step S4).

Described specifically, the thickness of the workpiece 11 is measured at two or more points in the grinding step S2, and at one or more points in the measurement step S3. In the tilt adjustment step S4, based on the thicknesses of the workpiece 11 as measured at the three points or more of different distances from the center of the workpiece 11, the tilt of the chuck table 4 or grinding wheel 24 is adjusted so as to reduce variations in the thickness of the workpiece 11.

Described more specifically, the controller 38 (see FIG. 1) first specifies a thickness distribution for the workpiece 11 based on the information on the thicknesses of the workpiece 11 as stored in the storage unit. For example, the controller 38 calculates the thickness distribution (shape of the workpiece 11) in the radial direction of the workpiece 11 by approximating the thicknesses of the workpiece 11 as measured at the three or more points. It is to be noted that, if the thickness of the workpiece 11 is measured a plurality of times at every measurement point in the grinding step S2 and measurement step S3, the averages of the thicknesses of the workpiece 11 at the respective measurement points may also be used in the calculation of the thickness distribution of the workpiece 11.

Next, control signals are outputted from the controller 38 to the fixed support member 16A and movable support members 16B of the tilt adjustment mechanism 12 (see FIG. 2), and a tilt is set for the chuck table 4 based on the thickness distribution of the workpiece 11 (the shape of the workpiece 11). As a consequence, the relative tilt of the holding surface 4a of the chuck table 4 and the grinding wheel 24 is adjusted such that the thickness variations of the workpiece 11 are reduced. If the workpiece 11 is preferentially ground at the central portion thereof due to variations in stock removal in the grinding step S2, for example, the workpiece 11 is ground thinner at the central portion thereof than at the outer peripheral portion thereof. In this case, the tilt of the chuck table 4 is changed such that the center of the workpiece 11 (the center of the holding surface 4a) moves apart from the rotation path of the grinding stones 28. If the workpiece 11 is preferentially ground at the outer peripheral portion thereof due to variations in stock removal in the grinding step S2, on the other hand, the workpiece 11 is ground thinner at the outer peripheral portion thereof than at the central portion thereof. In this case, the tilt of the chuck table 4 is changed such that the outer peripheral edge of the workpiece 11 (the outer peripheral edge of the holding surface 4a) moves apart from the rotation path of the grinding stones 28.

By adjusting the relative tilt of the holding surface 4a of the chuck table 4 and the grinding wheels 24 based on the thickness distribution of the workpiece 11 as described above, the workpiece 11 will be reduced in thickness variations in subsequent grinding. It is to be noted that no limitation is imposed on the timing at which the tilt adjustment is to be performed. For example, the tilt adjustment may be performed at every time that the grinding of the workpiece 11 is completed. The tilt adjustment may also be performed when the kind (material, shape, dimension, or the like) of the workpiece 11 to be ground by the grinding apparatus 2 or processing conditions are changed.

As described above, in the grinding method according to this embodiment, the thickness of the workpiece 11 is measured in the non-contact region B during the grinding of the workpiece 11, and the thickness of the workpiece 11 is measured in the contact region A after the grinding of the workpiece 11. As a consequence, the measurement time of the thickness of the workpiece 11 after the grinding of the workpiece 11 is shortened, and therefore the efficiency of grinding processing of the workpiece 11 is improved.

In the embodiment described above, the description is made about the case that the measurement step S3 and tilt adjustment step S4 are performed after the workpiece 11 has been ground to the finish thickness in the grinding step S2. However, the measurement step S3 and tilt adjustment step S4 can be performed in the course of the grinding of the workpiece 11. Described specifically, the workpiece 11 is first ground by the grinding wheel 24, and the grinding of the workpiece 11 is suspended before the thickness of the workpiece is reduced to the finish thickness (first grinding step). After performing the measurement step S3 and tilt adjustment step S4, the grinding of the workpiece 11 is resumed to grind the workpiece 11 to the finish thickness (second grinding step). It is to be noted that the grinding procedures of the workpiece 11 and the operations of the grinding apparatus 2 in the first grinding step and second grinding step are similar to those in the grinding step S2 (see FIGS. 5A and 5B). In the second grinding step described above, the workpiece 11 that was used in the measurement of the thickness distribution can be ground with an advance tilt adjustment. As a consequence, final thickness variations of the workpiece 11 used in the measurement of the thickness distribution can be reduced.

It is to be noted that, if the measurement step S3 and tilt adjustment step S4 are performed between the first grinding step and the second grinding step, the chuck table 4 and grinding unit 18 are preferably kept rotating in the measurement step S3 and tilt adjustment step S4. This enables to promptly resume, in the second grinding step, the grinding of the workpiece 11 that was suspended in the first grinding step.

Further, the grinding step S2, the measurement step S3, and the tilt adjustment step S4 may each be performed a plurality of times to grind the workpiece 11. In other words, while a single workpiece 11 is being ground, the measurement of the thickness of another workpiece 11 and the adjustment of the relative tilt between the holding surface 4a of the chuck table 4 and the grinding wheel 24 may each be performed a plurality of times. This enables to more effectively reduce thickness variations of the workpiece 11.

Moreover, the constructions, methods, and the like according to the above-described embodiment can be practiced with appropriate changes or modifications within the scope not departing from the object of the present invention.

The present invention is not limited to the details of the above-described preferred embodiment. The scope of the invention is defined by the appended claims and all changes and modifications as fall within the equivalence of the scope of the claims are therefore to be embraced by the invention.

What is claimed is:

1. A grinding method of a workpiece, comprising:
a holding step of holding the workpiece on a holding surface of a chuck table;
a grinding step of, after the holding step, measuring a thickness of the workpiece in a non-contact region other than a contact region between the workpiece and grinding stones while grinding the workpiece with a grinding wheel including the grinding stones; and
a measurement step of, after the grinding step, relatively moving and separating the workpiece and the grinding stones from each other, and measuring the thickness of the workpiece in the contact region during or after the relative movement of the workpiece and the grinding stones.

2. The grinding method according to claim 1, wherein,
in the grinding step and the measurement step, the thickness of the workpiece is measured at three or more points of different distances from a center of the workpiece, and
the grinding method further includes a tilt adjustment step of, after the measurement step, adjusting a relative tilt between the holding surface and the grinding wheel based on the thicknesses of the workpiece measured in the grinding step and the measurement step.

3. The grinding method according to claim 2, wherein the grinding step, the measurement step, and the tilt adjustment step are each performed a plurality of times to grind the workpiece.
